(19) United States
(12) Patent Application Publication
(10) Pub. No.: US 2007/0127614 A1
(43) Pub. Date: Jun. 7, 2007

(54) Communication device

(75) Inventor: Kenichi Kawakami, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/634,082

(22) Filed: Dec. 6, 2006

(30) Foreign Application Priority Data
Dec. 7, 2005 (JP) 2005-353386

(51) Int. Cl. H03D 3/24

(52) U.S. Cl. 375/373

(57) ABSTRACT

Disclosed is a communication circuit including a clock selection circuit (20) which receives CDR multiple-phase clocks (16) from a PLL (1) to a CDR circuit (7), selects one of the CDR multiple-phase clock signals (16) responsive to a clock selection signal (21), and outputs the selected clock signal. At a time of the loopback test, the clock signal selected by the clock selection circuit (20) is used as a transmit clock (11). Transmit data is looped back from an input/output terminal (4) to a receiver circuit (6). Data from the receiver circuit (6) is supplied to the CDR circuit (7), and comparison between recovered data from the CDR circuit (7) and expected value data is made by a comparison circuit (8), thereby conducting the test. By changing a phase of the transmit clock (11) by the clock selection circuit (20), a delay time (=tTx+tRx) which is a sum of a transmit circuit delay time (tTx) and a receiver circuit delay time (tRx) can be varied.

### FIELD OF THE INVENTION

The present invention relates to a loopback test for a communication device. More specifically, the invention relates to a loopback test for a bidirectional, high-speed communication device including a clock and data recovery (CDR) circuit supplied with multiple-phase clocks.

### BACKGROUND OF THE INVENTION

As a test for a bidirectional, high-speed communication circuit such as the one compliant with USB 2.0 (Universal Serial Bus Specification Revision 2.0), a loopback test has been routinely adopted. In the loopback test, a transmit signal from a transmit unit is directly looped back to a receiver unit, for test, in order to increase efficiency of the test of a transmit/receiver circuit.

Recently, in an advanced miniaturization process of a semiconductor device, a probability of occurrence of a delay failure as well as a function failure of a device that constitutes a circuit becomes higher. Accordingly, the realization of a high-speed test with a high accuracy is desired in a semiconductor device screening process.

Various types of loopback tests for a communication device including the clock and data recovery circuit (CDR circuit) which causes received data to be synchronized with an internal clock signal have been hitherto proposed. Patent Document 1, for example, discloses a configuration aimed at allowing a fault detection test for a transmitter/receiver of the communication device including the CDR circuit to be conducted in a communication state close to an actual operation, using the loopback test. In this device, switching control is performed so that at a time of a normal operation, an internal clock from a clock generation circuit that supplies multiple-phase clock signals to the CDR circuit is supplied as a receive clock, and at a time of the loopback test, the internal clock is supplied as the receive clock, and a modulated clock signal from a clock modulation circuit is supplied as a transmit clock. The clock modulation circuit in this Patent Document 1 includes a counter that performs counting in synchronization with an external trigger and a selector circuit that receives the multiple-phase clock signals from the clock generation circuit and selectively outputs one of the clock signals in accordance with a count value, as the modulated clock signal.

Patent Document 2 discloses a semiconductor integrated circuit device including a first receiver unit, a first transmit unit, a second receiver unit, and a second transmit unit, as a configuration for solving a problem in which a fault detection rate of the CDR circuit cannot be increased by a loopback test method capable of testing a receiving portion without using an expensive tester. The first receiver unit includes a first CDR circuit capable of recovering a clock from received serial data and also changing a phase of a clock to be generated. The first transmit unit includes a first serializer that converts parallel data to serial data synchronized with either of a transmit clock and the clock generated by the first CDR circuit. The second receiver unit includes a second CDR circuit capable of recovering a clock from received serial data and also changing a phase of a clock to be generated. The second transmit unit includes a second serializer that converts parallel data to serial data synchronized with either of the transmit clock and the clock generated by the second CDR circuit. The semiconductor integrated circuit device has made it possible to improve the fault detection rate.

FIG. 9 is a diagram showing a typical configuration of a loopback test circuit in a conventional communication device including the CDR circuit. Referring to FIG. 9, this communication device includes a PLL (Phase Locked Loop) 1 (that is configured as an analog PLL), a D-type flip-flop (DFF) 2, a transmit circuit (driver) 3, a termination resistor 5, a receiver circuit 6, a CDR circuit 7′, a comparison circuit 8, and a control logic circuit (LOGIC) 9. The PLL 1 generates a plurality of clock signals (multi-phase clock signals) 16 with phases thereof mutually different to one another. The D-type flip-flop 2 receives transmit data (first transmit data) 10 at a data terminal thereof, and samples the transmit data responsive to a transmit clock 11 supplied to a clock input terminal thereof. The transmit circuit 3 receives an output of the D-type flip-flop 2 and outputs a transmission signal to the input/output terminal 4. The termination resistor 5 is connected between the input/output terminal 4 and a ground potential. An input terminal of the receiver circuit 6 is connected to the input/output terminal 4. The CDR circuit 7′ is supplied with received data 13 from the receiver circuit 6, recovers a recovered clock 15 from the received data 13 and outputs the recovered clock 15, and also outputs recovered data. The comparison circuit 8 compares the recovered data 14 from the CDR circuit 7′ with comparison source data 17. The control logic circuit 9 controls the test.

From the PLL1, the clock signals (referred to as “CDR multiple-phase clocks”) 16 with the phases thereof mutually different to one another are supplied to the CDR circuit 7′. The CDR multiple-phase clocks 16 constituted from clock signals φ1 to φn have phase differences at equal intervals, respectively. When a transfer rate of serial data (per one clock cycle) is indicated by t rate, each phase difference (time interval) between clocks becomes t rate/n.

One clock signal (indicated by φ1 in FIG. 9) of the multiple clocks 16 is supplied to the control logic circuit 9 and the clock terminal of the D-type flip-flop 2 for transmission, as the transmit clock 11.

The first transmit data 10 synchronized with this transmit clock 11 is supplied to the D-type flip-flop 2 from the control logic circuit 9. An output signal of the D-type flip-flop 2 is supplied to the transmit circuit 3 as second transmit data 12.

The transmit circuit 3 outputs to the input/output terminal 4 the second transmit data 12 with a certain delay and a certain amplitude.

A signal from the input/output terminal 4 is supplied to the receiver circuit 6 without alteration at a time of the loopback test. The receiver circuit 6 outputs the received data 13 to the CDR circuit 7′.

The CDR circuit 7′ detects an edge of the received data 13, selects a clock signal from among the multiple-phase clocks 16 (constituted from the clock signals φ1 to φn) supplied from the PLL 1, which is delayed from a transition edge of the received data 3 by a predetermined phase, (that is, a rising edge of the selected clock signal is delayed by a phase corresponding to a time period from the transition edge of the received data 13 to the middle portion of the received data 13), and outputs the selected clock signal to the control logic circuit 9 as the recovered clock 15. The CDR circuit 7′ further synchronizes the received data 13 with the selected clock signal, and the synchronized received data to the control logic circuit 9, as the recovered data 14. Concurrently with this, the CDR circuit 7′ outputs a reception start signal 19 to the control logic circuit 9 and the comparison circuit 8, thereby notifying that the data has been normally received.

The comparison circuit 8 starts comparison between the comparison source data (expected value data) 17 output from the control logic circuit 9 with the recovered data 14 recovered by the CDR circuit 7′ from a time immediately after the reception start signal 19 has changed, detects whether the data transmitted is correctly looped back, in the form of a comparison result 18, and outputs the comparison result 18 to the control logic circuit 9. Meanwhile, the control logic circuit 9 includes a pattern generator (not shown) that generates the first transmit data 10 for the test.

FIG. 10 is a diagram showing an example of operation waveforms in the circuit shown in FIG. 9. Names of signals of the respective waveforms correspond to those shown in FIG. 9. The multiple-phase clocks 16 output from the PLL 1 to the CDR circuit 7′ are set to have eight phases. The transmit data in FIG. 10 have NRZ (Non-Return to Zero) waveforms. The first transmit data 10 is synchronized with the phase of the first-phase clock signal φ1. The received data 13, which is an output of the receiver circuit 6, is supplied to the CDR circuit 7′, and output as the recovered data 14 synchronized with a rising edge of the recovered clock 15.

Herein, a transmission circuit delay time (tTx) is defined to be a delay time from a rising edge of the first-phase clock signal φ1 to a transition (a rising transition in FIG. 10) of a signal level of the input/output terminal 4. A receiver circuit delay time (tRx) is defined to be a delay time from the transition of the signal level of the input/output terminal 4 to a transition of the received data 13, which is the output of the receiver circuit 6.

The second transmit data 12, which is output data of the D-type flip-flop 2, is looped back to an input of the CDR circuit 7′ as the received data 13 (output of the receiver circuit 6) with a delay time equal to a sum of the delay times of the transmitting and receiver circuits (tTx+tRx).

The sum of the delay times (tTx+tRx) assumes a value determined by a variation factor of a semiconductor device, temperature, and supply voltage. Accordingly, the sum of the delay times is constant under an environment where these factors do not vary.

For this reason, when loopback is performed at a timing as shown in FIG. 10, the clock signal φ3 of a third phase is detected as a synchronizing edge (which means that a timing of a rising edge of the clock signal φ3 matches a timing of a transition edge of the received data 13), and the clock signal φ7 of a seventh phase is output as the recovered clock 15 (because a rising edge of the clock signa φ7 corresponds to a middle between edges of the received data 13, the clock signal φ7 is selected as the recovered clock 15). The recovered data 14 output from the CDR circuit 7′ is synchronized with the clock signal φ7 of a seventh phase, and is output. Concurrently, the reception start signal 19 is set to be HIGH.

The comparison circuit 8 compares the comparison source data 17 supplied from the control logic circuit 9 with the recovered data 14. When they match to each other, for example, the comparison circuit 8 outputs a HIGH level signal as the comparison result 18, for example, in order to indicate PASS (good).
[Patent Document 1]
   JP Patent Kokai Publication No. JP-P2004-260677A
[Patent Document 2]
   JP Patent Kokai Publication No. JP-P2005-077274A

### SUMMARY OF THE DISCLOSURE

As described above, in the loopback test described with reference to FIGS. 9 and 10, the delay time in the environment where the delay time constituted from the sum of the delay times of the transmitting and receiver circuits (tTx+tRx) is constant is uniquely determined. Then, after a system has been stabilized, a phase of the recovered clock 15 selected within the CDR circuit 7′ will not be changed. As the recovered clock 15, the seventh-phase clock signal φ7 among the CDR multiple-phase clocks 6 is always selected, as shown in FIG. 10, for example.

For this reason, even if the recovered data 14 synchronized with the clock signal (recovered clock) selected by the CDR circuit 7′ is compared with the comparison source data 17 in the loopback test, only the connection of one clock line and operations of some circuits are substantially checked.

That is, there is a problem that when a failure such as disconnection in other clock line that does not contribute to the operation has arisen, or when an abnormal condition has been encountered in a circuit other than the some circuits, such a condition cannot be detected as a failure in the loopback test. In other words, clock connections and all circuits within the CDR circuit cannot be tested. A fault detection coverage by the test is restricted (or a test performance is unsatisfactory).

The above described problem is solved by the present invention, in which there is added a clock selection circuit capable of selecting a phase of a transmit clock at a time of a loopback test, wherein a phase relationship between the transmit clock and a recovered clock from a CDR circuit is shifted in the loopback test, thereby allowing entire clock line connections and entire recovery circuits in the CDR circuit to be tested.

A communication device according to one aspect of the present invention includes:

a clock generation circuit that generates multiple-phase clocks constituted from a plurality of clock signals with phases thereof being different to one another; and

a clock and data recovery circuit that receives the multiple-phase clocks from said clock generation circuit, selects from among the multiple-phase clocks a clock signal synchronized with received data to recover data, and outputs the selected clock signal as a recovered clock; wherein a loopback test for said communication device is conducted by looping back a transmit signal from a transmit circuit to a receiver circuit, supplying the received data from the receiver circuit to said clock and data recovery circuit, and comparing the recovered data from said clock and data recovery circuit with expected value data;

said communication device further comprising a circuit that selects a clock signal of one phase from among the multiple-phase clocks supplied from said clock generation circuit to said clock and data recovery circuit responsive to an input clock selection signal, and supplies the selected clock signal as a transmit clock; wherein the loopback test is allowed to be conducted with a delay time of said transmit circuit defined based on the transmit clock being variably set.

The present invention includes:

a clock generation circuit that generates multiple-phase clocks constituted from a plurality of clock signals with phases thereof being different to one another;

a clock and data recovery circuit that receives the multiple-phase clocks from the clock generation circuit and selects from among the multiple-phase clocks a clock signal synchronized with input data, thereby recovering data; and

a clock selection circuit that receives the multiple-phase clock signals supplied from the clock generation circuit to the clock and data recovery circuit, selects a clock signal of one phase from among the multiple-phase clocks based on a supplied clock selection signal, and outputs the selected clock signal;

at a time of a loopback test, the clock signal selected by the clock selection circuit being supplied to a circuit that generates transmit data for the loopback test and a circuit that latches the generated transmit data, as a transmit clock;

the transmit data being looped back from an output of a transmit circuit to a receiver circuit, and then being supplied to the clock and data recovery circuit;

wherein with the change of selection of the clock signal by said clock selection circuit, a delay time from the transmit data is output to when the transmit data is output from said receiver circuit as received data is allowed to be variably set.

In the present invention, it may be so arranged that the clock and data recovery circuit outputs a first selected clock signal indicating which clock signal in the order of phases among the CDR multiple-phase clocks has been selected;

the communication device further comprises a first counter circuit that receives the first selected clock signal;

when the first selected clock signal indicates continuous selection of the clock signal of one phase from among the multiple-phase clocks for a predetermined period, said first counter circuit detects the continuous selection, and outputs a result of the detection in the form of a second selected clock signal; and

which clock signal in the order of phases from among the multiple-phase clocks is selected as the recovered clock by said clock and data recovery circuit is thereby enabled to be identified.

In the present invention, it may be so arranged that the multiple-phase clocks include clocks (φ1 to φn) with first through nth phases thereof separated at equal intervals;

the first selected clock signal include n signals (s1 to sn) corresponding to the clocks of the first through nth phases, respectively; and

when said clock and data recovery circuit selects as the recovered clock the clock signal of the ith phase from among the clock signals of the first through nth phases of the multiple-phase clocks, in which i is an integer from 1 to n, the ith signal (si) of the first selected clock signal is activated, corresponding to the clock signal of the ith phase.

In the present invention, it may be so arranged that the first counter circuit includes n counters that input the n signals (s1 to sn) constituting the first selected clock signal from the clock and data recovery circuit, respectively;

each of the n counters performs counting of an input clock signal while a corresponding one of the n signals (s1 to sn) constituting the first selected clock signal is active, and outputs the output signal that is active when a predetermined count value is reached; and

the first counter circuit includes a circuit that performs control so that when one of the n outputs of said n counters is activated, transmission of the clock signal to said n counters is cut off.

The present invention may include:

a second counter circuit including:

a selector circuit that receives the first selected clock signal of the first counter circuit as a clock switching signal, receives first and second clock input signals, and selects one of the first and second clock input signals based on the clock switching signal; and

a counter that counts an output of the selector circuit;

a count output of the second counter circuit being supplied to the clock selection circuit as the clock selection signal.

In the present invention, it may be so arranged that the second selected clock signal is constituted from n signals (t1 to tn) corresponding to n signals (s1 to sn) of the first selected clock signal, respectively, and one of the n signals of the second selected clock signals is supplied to the second counter circuit as a clock switching signal.

The meritorious effects of the present invention are summarized as follows.

According to the present invention, in the loopback test for a bidirectional communication circuit including a CDR that receives multiple phase clocks, clock connections and all circuits within the CDR circuit can be tested at a high speed.

According to the present invention, in the loopback test for the bidirectional communication circuit that receives the multiple phase clocks, a failure in the clock selection circuit can be detected.

According to the present invention, in the loopback test for the bidirectional communication circuit that receives the multiple phase clocks, the test for detecting a failure in the clock selection circuit can be started in the same state.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram showing a configuration of a first embodiment of the present invention;

FIG. 2 is a diagram showing operation waveforms in the first embodiment of the present invention;

FIG. 3 is a diagram showing a configuration of a second embodiment of the present invention;

FIG. 4 is a diagram showing a configuration of a counter circuit in the second embodiment of the present invention;

FIG. 5 is a diagram showing operation waveforms of the counter circuit in the second embodiment of the present invention;

FIG. 6 is a diagram showing a configuration of a third embodiment of the present invention;

FIG. 7 is a diagram showing a configuration of a second counter circuit in the third embodiment of the present invention;

FIG. 8 is a diagram showing operation waveforms of the second counter circuit in the third embodiment of the present invention;

FIG. 9 is a diagram for explaining a loopback test in a conventional communication device; and

FIG. 10 is a diagram showing operation waveforms in the loopback test in the communication device in FIG. 9.

### DETAILED DESCRIPTION OF THE INVENTION

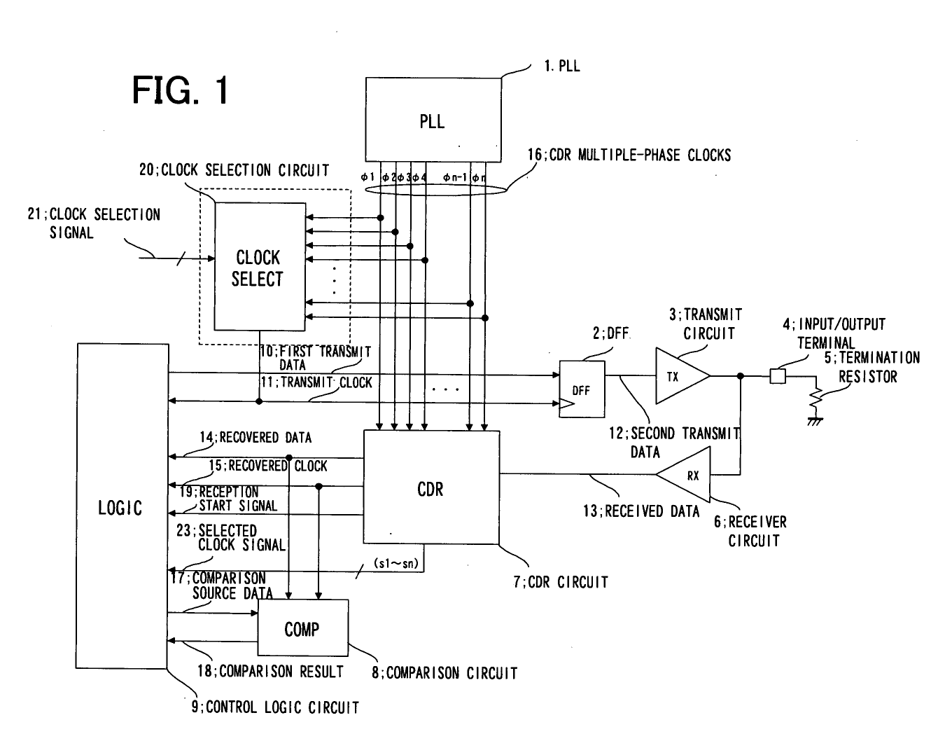

A description of the present invention will be given with reference to appended drawings. Referring to FIG. 1, a configuration according to a first aspect of the present invention includes a clock selection circuit (20) that receives CDR multiple-phase clocks (16) supplied from a PLL (1) to a CDR circuit (7), selects one of the CDR multiple-phase clock signals (16) based on a clock selection signal (21) supplied from outside, and outputs the selected one of the CDR multiple-phase clock signals (16). At a time of a loopback test, an output of the clock selection circuit 20 is used as a transmit clock (11). Transmit data is looped back from an input/output terminal (4) to a receiver circuit (6). Data from the receiver circuit (6) is supplied to the CDR circuit (7). Then, by comparing recovered data from the CDR circuit (7) with comparison source data (expected value data) at a comparison circuit (8), the test using loopback (functional test) is conducted. By changing a phase of the transmit clock (11) by the clock selection circuit (20), a delay time, which is a sum of delay times of a transmit circuit and the receiver circuit (tTX+tRx) is made to be varied and then, the loopback test can be conducted.

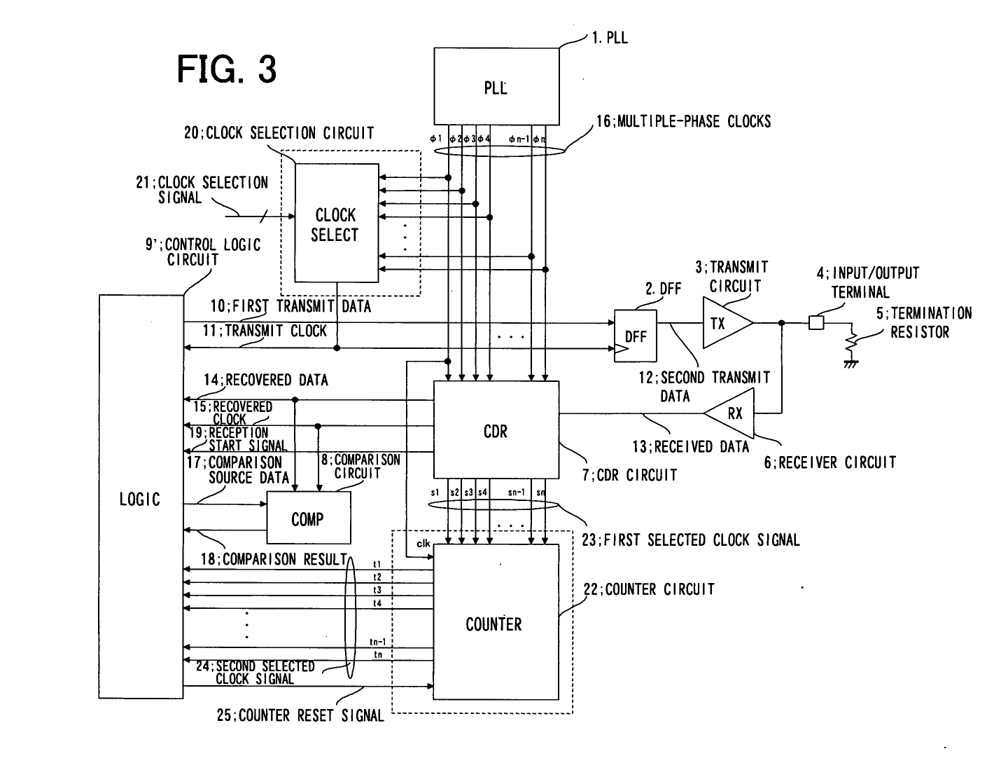

Referring to FIG. 3, in a second aspect of the present invention, a result of clock selection in the CDR circuit (7) (which one of the CDR multiple-phase clocks (16) has been selected as a recovered clock (15) as a first selected clock signal (23) is output, in addition to the configuration of the above described first aspect. In the second aspect of the present invention, there is further provided a counter circuit (22) that receives the first selected clock signal (23). The counter circuit (22) detects that the first selected clock signal (23) keeps a predetermined logic level (such as a HIGH level) for a certain period (indicating that a clock signal of a certain phase has been selected for the certain period as the recovered clock), and outputs a result of the detection to a control logic circuit (9′) in the form of a second selected clock signal (24). With this arrangement, the control logic circuit (9′) can identify what number clock signal in the order of phases among the CDR multiple-phase clocks has been selected in the CDR circuit (7) as the recovered clock (15).

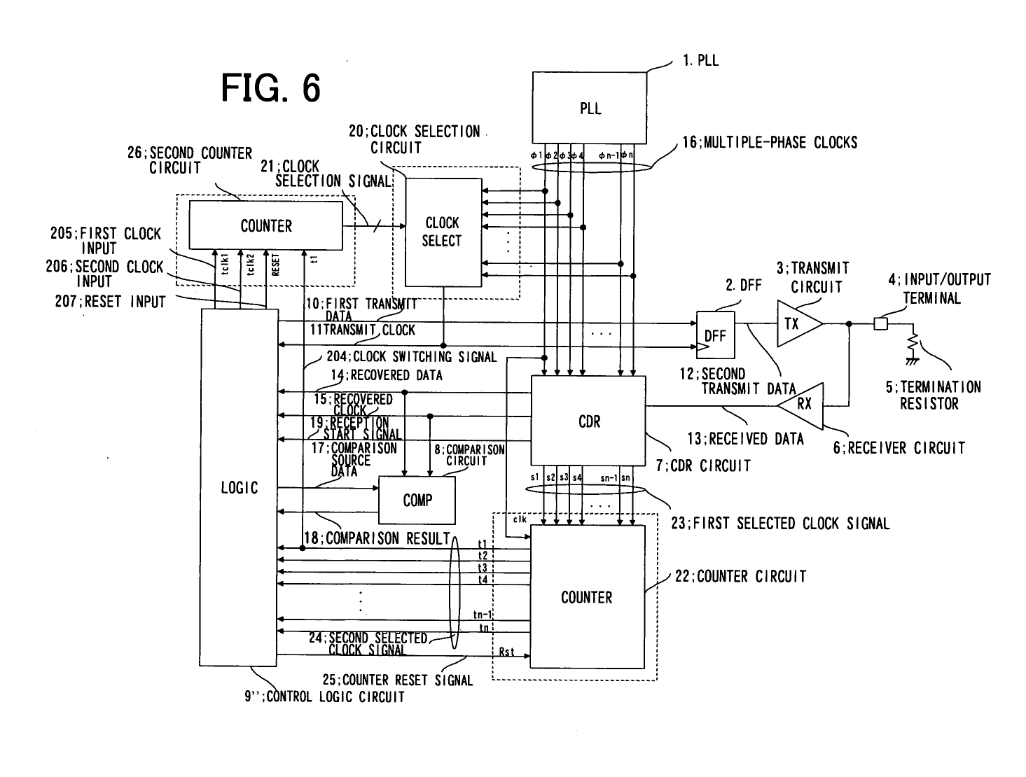

Referring to FIG. 6, in a third aspect of the present invention, there is further provided a second counter circuit (26) that receives the first selected clock signal (23) from the counter circuit (22) as a clock switching signal (204), and includes a first clock input (205) and a second clock input (206). An output of the second counter circuit (26) is used as the clock selection signal (21). Then, using the clock switching signal (204), a clock input to the second counter circuit (26) is switched. A description will be given below in connection with exemplary embodiments.

FIG. 1 is a diagram showing a configuration of a first embodiment of the present invention. Referring to FIG. 1, this embodiment includes the PLL circuit 1 (which is an analog PLL), a D-type flip-flop (DFF) 2, a transmit circuit 3 (which is a driver), the input/output terminal 4, a termination resistor 5, the receiver circuit 6 (which is a receiver), the CDR circuit 7, the comparison circuit 8, and a control logic circuit 9 that controls the test. This embodiment further includes the clock selection circuit 20 that receives the multiple-phase clocks 16 output from the PLL 1, selects one of the multiple-phase clocks 16 (of n-phase clocks φ1 to φn in FIG. 1) according to the clock selection signal 21 input from outside, and outputs the selected clock as the transmit clock 11.

From the PLL 1, the clock signals (referred to as “CDR multiple-phase clocks”) 16 with phases thereof being different to one another are supplied to the CDR circuit 7.

One of the clock signals having a certain phase among the multiple-phase clocks 16 is selected by the clock selection circuit 20, and is supplied to the control logic circuit 9 and a clock terminal of the D-type flip-flop 2 for transmission, as the transmit clock 11.

The control logic circuit 9 outputs first transmit data 10 synchronized with the transmit clock 11 selected by the clock selection circuit 20. An output signal of the D-type flip-flop 2 is supplied to the transmit circuit 3 as second transmit data 12.

The transmit circuit 3 outputs to the input/output terminal 4 the received second transmit data 12 with a certain delay and a certain amplitude.

At a time of the loopback test, a signal from the input/output terminal 4 is supplied to the receiver circuit 6 without alteration. Received data 13 output-from the receiver circuit 6 is supplied to the CDR circuit 7.

The CDR circuit 7 detects a transition edge of the input received data 13, and selects the clock signal from among the multiple-phase clocks 16 supplied from the PLL 1, delayed just by a predetermined phase from the transition edge of the received data 13. The transition edge of the selected clock signal corresponds to the middle of the received data. The CDR circuit 7 outputs the selected clock signal to the control logic circuit 9 as the recovered clock signal 15, and also synchronizes the received data 13 with the selected clock signal. Then, the CDR circuit 7 outputs the synchronized received data 13 to the control logic circuit 9 as recovered data 14. The CDR circuit 7 also outputs a reception start signal 19 to the control logic circuit 9 and the comparison circuit 8, notifying that the data has been normally received.

In this embodiment, the CDR circuit 7 outputs to the control-logic circuit 9 a signal indicating which clock has been selected as the recovered clock 15 in the form of a selected clock signal 23 (constituted from signals s1 to sn). When an ith phase clock signal φi (1≦i≦n) among the CDR multiple-phase clocks 16 (constituted from the clocks φ1 to φn) has been selected as the recovered clock 15, the signal si among the selected clock signal 23 (constituted from the signals s1 to sn) is set to HIGH, and the other signals are made to remain LOW.

The comparison circuit 8 compares comparison source data 17 output from the control logic circuit 9 with the recovered data 14 recovered by the CDR circuit 7 immediately after the reception start signal 19 has been changed, detects whether the transmit data is correctly looped back in the form of a comparison result 18, and outputs the comparison result 18 to the control logic circuit 9.

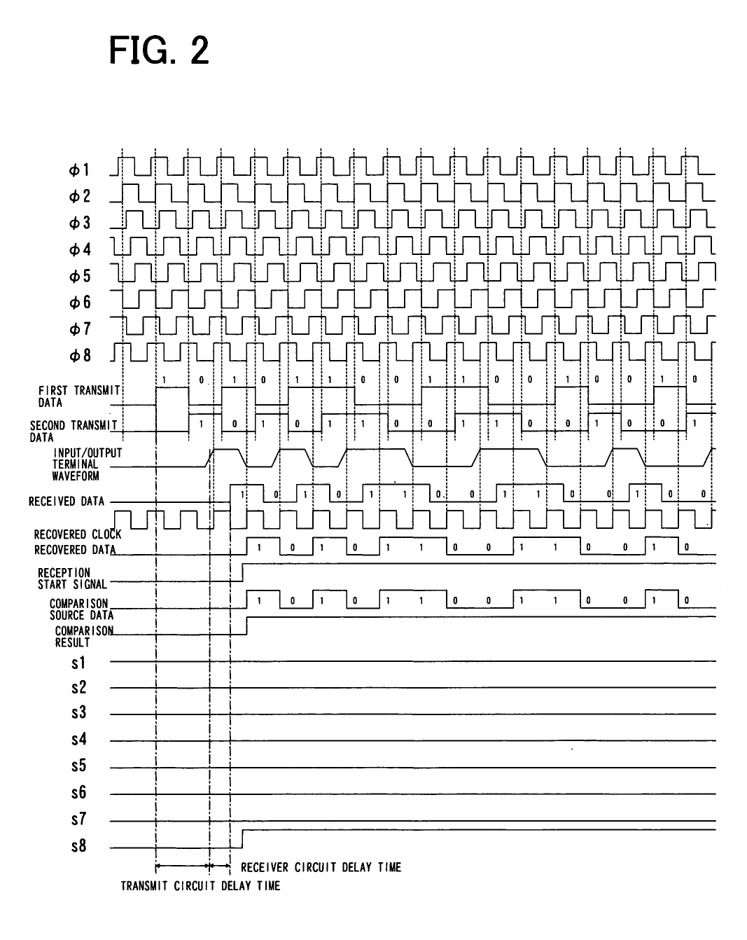

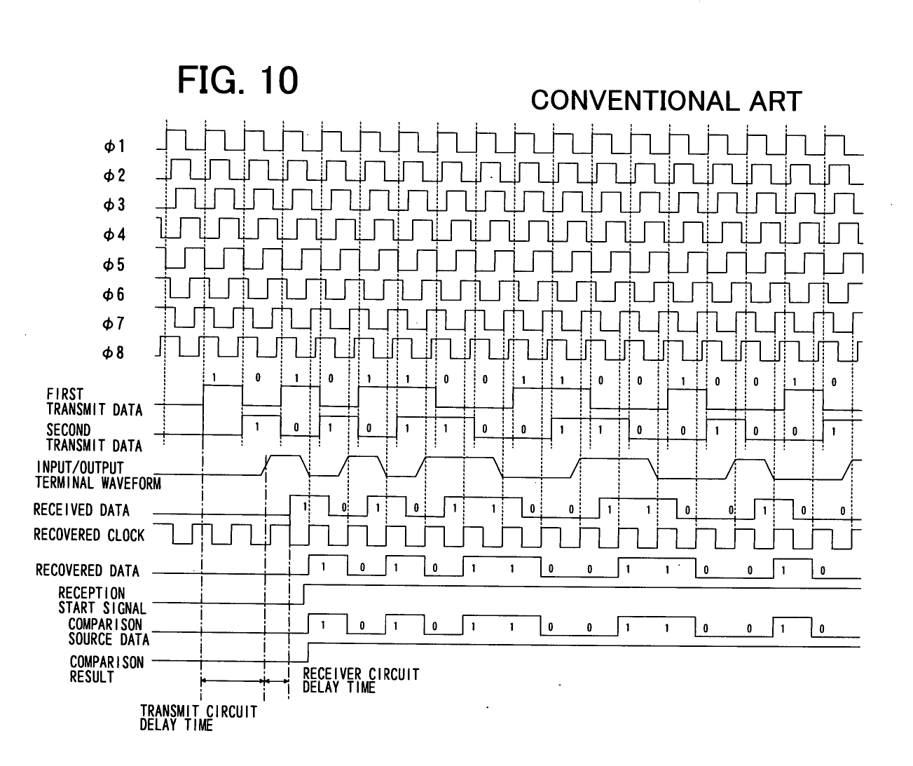

FIG. 2 is a diagram showing operation waveforms in this embodiment. Though no particular limitation is imposed, the number of phases of the multiple-phase clocks 16 in FIG. 1 is set to eight phases (of the clock signals φ1 to φ8) in FIG. 2. FIG. 2 is compared with FIG. 10. Then, when a phase of an output of the clock selection circuit 20 is switched from the phase of the first phase clock φ1 (refer to FIG. 10) to the phase of the second phase clock φ2 (refer to FIG. 2) according to the clock selection signal 21, the first transmit data 10 and the second transmit data 12 are also delayed from the first phase clock φ1 by trate/n (in which trate indicates the rate per clock cycle, while trate/n indicates a phase difference between the clocks). Thus, the recovered clock 15 selected by the CDR circuit 7 is changed from the seventh phase clock φ7 (refer to FIG. 10) to the eighth phase clock φ8 (refer to FIG. 2). Then, the signal s8 of the selected clock signal 23 in a HIGH level is output.

Next, when the phase of the output of the clock selection circuit 20 is changed from the phase of the second phase clock φ2 to the phase of the third phase clock φ3, the recovered clock 15 selected by the CDR circuit 7 is looped back from the eighth phase clock φ8 to the first phase clock φ1. Then, the signal s1 of the selected clock signal 23 in the HIGH level is output, in a like manner.

By sequentially changing the clock selection signal 21 by the number of bits (eight bits in an example of FIG. 2) corresponding to each of the multiple-phase clocks 16 (constituted from the clock signals φ1 to φ8), and by changing the phase of the transmit clock 11 output from the clock selection circuit 20 as described before, it becomes possible to test all combinations of connections of the clocks selected by the CDR circuit 7 and to operate all circuits in the CDR circuit 7.

Further, by monitoring switching of the selected clock signal 23 (constituted from the signals s1 to s8) from the CDR circuit 7 (switching of the signal in the HIGH level from the signal si to the signal sj, in which i≠j, 1≦i, and j≦n), a fault within the clock selection circuit 20 can also be detected. When the transmit clock 11 is sequentially switched from the clock signal φ1 to the clock signal φ8 according to the clock selection signal 21, and when switching of the selected clock signal 23 (constituted from the signals s1 to s8) from the CDR circuit 7 is not performed, it is determined that there is the fault within the clock selection circuit 20.

Next, a second embodiment of the present invention will be described. FIG. 3 is a diagram showing a configuration of the second embodiment of the present invention. Referring to FIG. 3, same reference characters are assigned to components that are the same as those in FIG. 1. This embodiment further includes a counter circuit 22 that receives the selected clock signal (referred to as a “first selected clock signal) (constituted from the signals s1 to sn) 23 output from the CDR circuit 7.

In this embodiment, the first selected clock signal 23 (constituted from the signals s1 to sn) from the CDR circuit 7 indicates which clock signal with which phase is currently selected from among the CDR multiple-phase clocks 16 as the recovered clock 15 inside the CDR circuit 7, as in the first embodiment in FIG. 1 described before. That is, when the ith phase clock signal φi (in which 1≦i≦n) is selected inside the CDR circuit 7, the signal si of the first selected clock signal 23 (constituted from the signals s1 to sn) is set to HIGH. When the phase of the clock signal selected inside the CDR circuit 7 as the recovered clock is not changed (when the clock signal φi is continued to be selected), the signal si is kept at HIGH.

The counter circuit 22 is reset by a counter reset signal 25, counts the first selected clock signal 23 for a certain period for stabilization, and outputs the first selected clock signal 23 as the second selected clock signal 24 (constituted from signals t1 to tn).

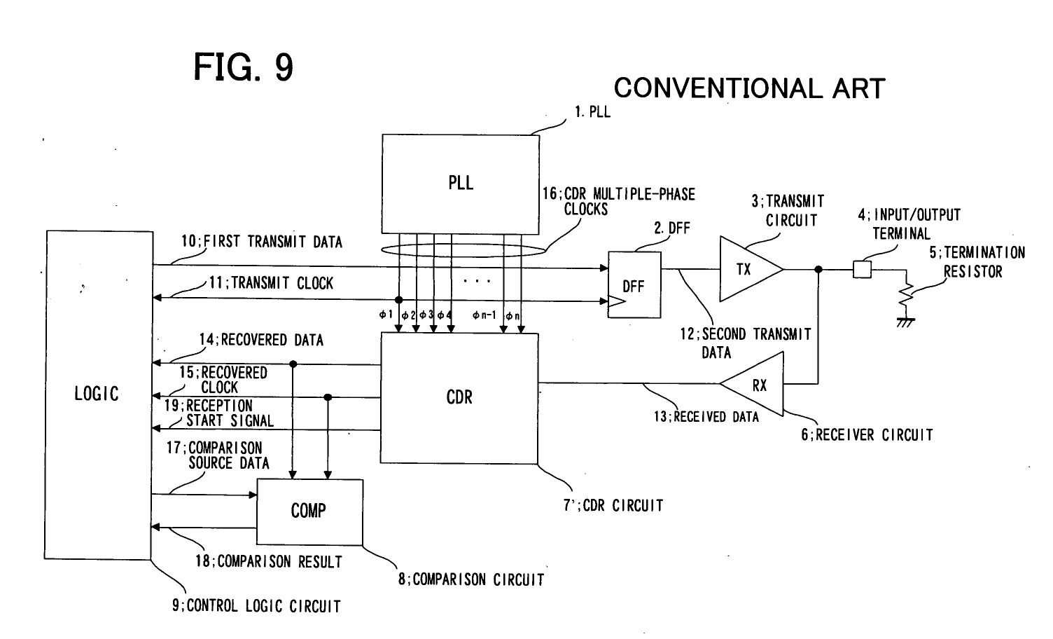

When the clock selection circuit 20 has failed and the phase of the transmit clock 11 is not switched in the first embodiment described before, the same operation as that in FIG. 9 will be performed. For this reason, the first embodiment cannot detect a fault in the CDR circuit 7.

Accordingly, in order to detect the fault in the clock selection circuit 20, it is necessary to monitor the first selected clock signal 23 (constituted from the signals s1 to sn) output from the CDR circuit 7 and confirm that the phase of the recovered clock 15 is changed in response to switching of the phase of the transmit clock 11.

Further, when the recovered clock 15 selected by the CDR circuit 7 is in the vicinity of a boundary of the clocks having adjacent phases among the multiple-phase clocks 16 (constituted from the clocks φ1 to φn), the first selected clock signal 23 will become unstable, and will alternately output values before and after the boundary.

In this embodiment, the counter circuit 22 is provided. Only when the HIGH level of the signal si (1≦i≦n) of the first selected clock signal 23 is continuously output for a certain period or more, the second selected clock signal 24 is output to the control logic circuit 9′.

The counter reset signal 25 is the reset signal for the counter circuit 22. The counter reset signal 25 is output every time when the clock selection signal 21 is changed.

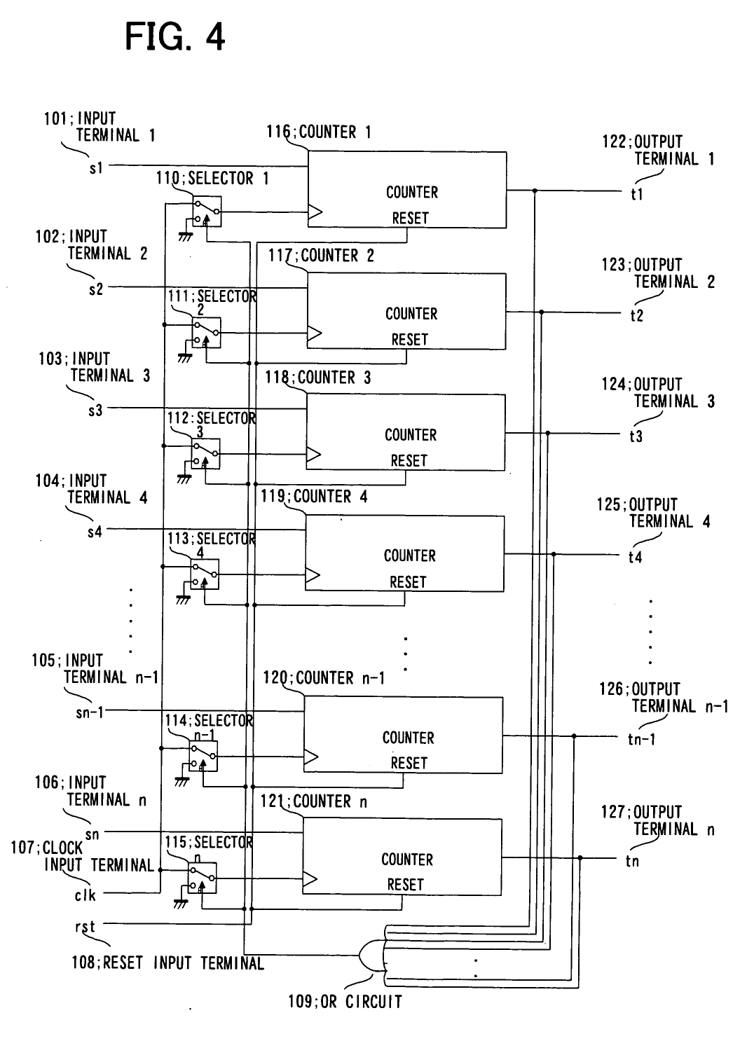

FIG. 4 is a diagram showing an example of a configuration of the counter circuit 22 shown in FIG. 3. Referring to FIG. 4, reference numerals 101 through 106 indicate input terminals for receiving the first selected clock signal 23 in FIG. 3, and reference numerals 122 through 127 indicate output terminals for outputting the second selected clock signal 24 in FIG. 3. Reference numeral 107 indicates a clock input terminal, and reference numeral 108 indicates a reset input terminal. Reference numerals 110 through 115 indicate selectors each of which selects whether to transmit the clock to a subsequent stage or interrupt the clock. A counter 116 is constituted from a counter circuit which outputs the HIGH level to the output terminal 122 when the HIGH level of the input terminal 101 is continued for a certain period or longer, or when a count value of the clock during a HIGH level period of the input terminal 101 is constant. A counter 117 is constituted from a counter circuit which outputs the HIGH level to the output terminal 123 when the HIGH level of the input terminal 102 is continued for the certain period or longer, or when a count value of the clock during a HIGH level period of the input terminal 102 is constant. A counter 118 is constituted from a counter circuit which outputs the HIGH level to the output terminal 124 when the HIGH level of the input terminal 103 is continued for the certain period or longer, or when a count value of the clock during a HIGH level period of the input terminal 103 is constant. A counter 119 is constituted from a counter circuit which outputs the HIGH level to the output terminal 125 when the HIGH level of the input terminal 104 is continued for the certain period or longer, or when a count value of the clock during a HIGH level period of the input terminal 104 is constant. A counter 120 is constituted from a counter circuit which outputs the HIGH level to the output terminal 126 when the HIGH level of the input terminal 105 is continued for the certain period or longer, or when a count value of the clock during a HIGH level period of the input terminal 105 is constant. A counter 121 is constituted from a counter circuit which outputs the HIGH level to the output terminal 127 when the HIGH level of the input terminal 106 is continued for the certain period or longer, or when a count value of the clock during a HIGH level period of the input terminal 106 is constant.

The first through nth output terminals 122 to 127 are connected to first through nth inputs of an n-input OR circuit 109, respectively. An output of the n-input OR circuit 109 are connected to control terminals of the first through nth selectors 110 to 115, respectively. When one of the first through n-th counter circuits 116 to 121 outputs the HIGH level, the output of the n-input OR circuit 109 goes HIGH. Then, all of the first through nth selectors 110 to 115 select to change from a clock input (clk) to a GND potential (fixed at LOW) for output. Clock supply to the first through nth counter circuits 116 to 121 is thereby cut off, and the first through nth counter circuit 116 to 121 maintain respective output states thereof.

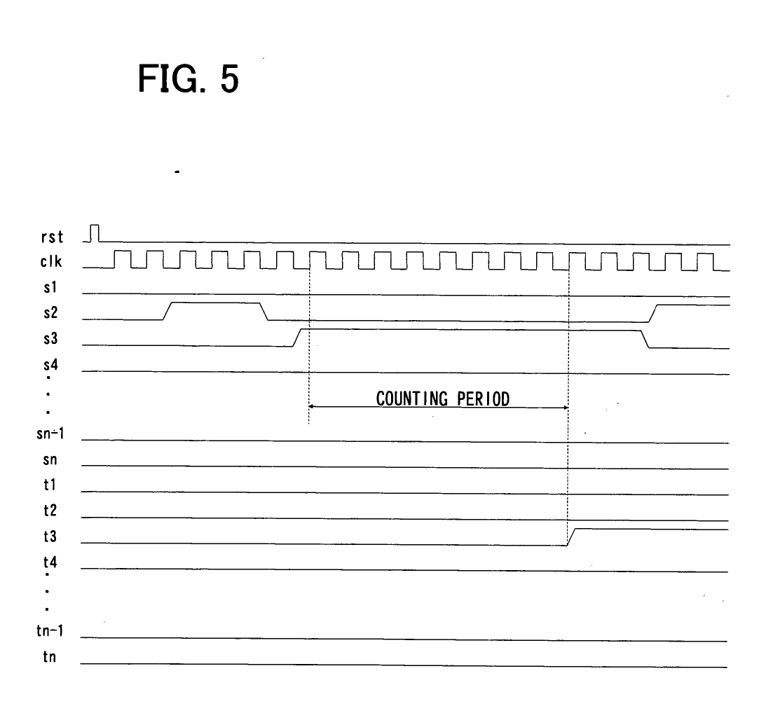

FIG. 5 is a diagram showing an example of operation waveforms of the counters 116 to 121 in FIG. 4. The counters 116 to 121 are reset by a reset signal from the reset input terminal 108 at a time of starting the test. Then, the signals s2 and s3 of the first selected clock signal are alternately selected. If the signal s3 is kept at HIGH for the certain period or longer, the signal t3 is changed to HIGH. A counting operation is thereby stopped.

Next, a third embodiment of the present invention will be described. FIG. 6 is a diagram showing a configuration of the third embodiment of the present invention. Referring to FIG. 6, the third embodiment of the present invention further includes a second counter circuit 26 in addition to the configuration of the second embodiment. The second counter circuit 26 is supplied with two types of clock signals 205 and 206 (tclk1 and tclk2) from a control logic circuit 9″. The second counter circuit 26 is supplied with one signal t1 of the second selected clock signal 24 from the counter circuit 22, as the clock switching signal 204.

An output of the second counter circuit 26 is supplied to the clock selection circuit 2 as the clock selection signal 21. That is, in this embodiment, the clock selection signal 21 is generated in the second counter circuit 26, thereby eliminating the need for an external terminal or the like for receiving the clock selection signal 21. Then, before and after clock switching by the clock selection circuit 20 based on the clock selection signal 21, control is performed so that phases of the clock signals selected from among the multiple-phase clocks 16 as transmit clocks are adjacent to each other, for example.

A reset signal input 207 is an input from the control logic circuit 9″ in order to reset the second counter circuit 26 at the initial time of the test.

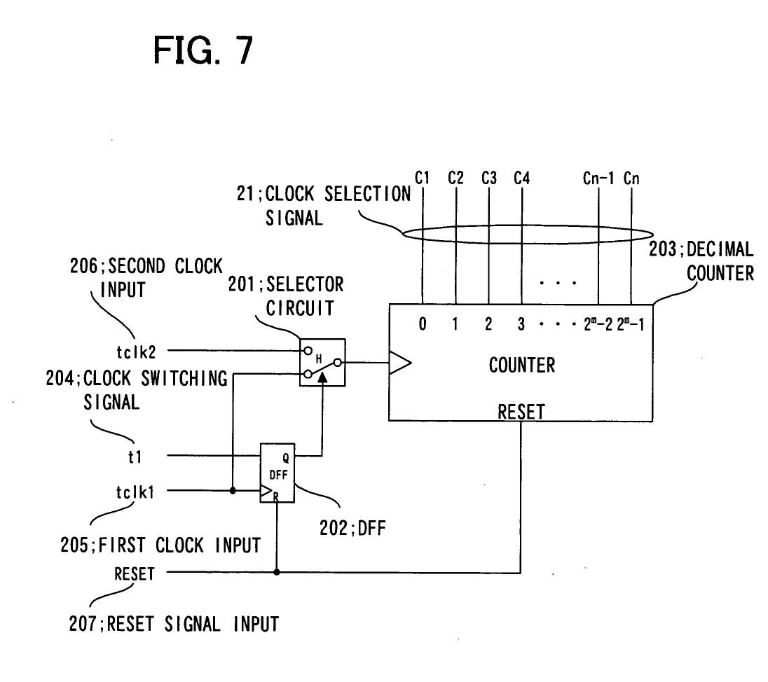

FIG. 7 is a diagram showing an example of a configuration of the second counter circuit 26 in FIG. 6. Referring to FIG. 7, the second counter circuit 26 includes a selector circuit 201, a D-type flip-flop 202, and a decimal counter 203. The selector circuit 201 performs switching between the first clock input signal (tclk1) and the second clock input signal (tclk2). The D-type flip-flop 202 is supplied with the first clock input signal (tclk1) at a clock input terminal thereof, and with the clock switching signal 204 (t1) at a data terminal thereof. An output signal from an output terminal Q of the D-type flip-flop 202 is supplied to the selector 201 as a selection control signal.

The decimal counter 203 receives an output of the selector circuit 201. Count outputs (C1 to Cn) are supplied to the clock selection circuit 20 as the clock selection signal 21.

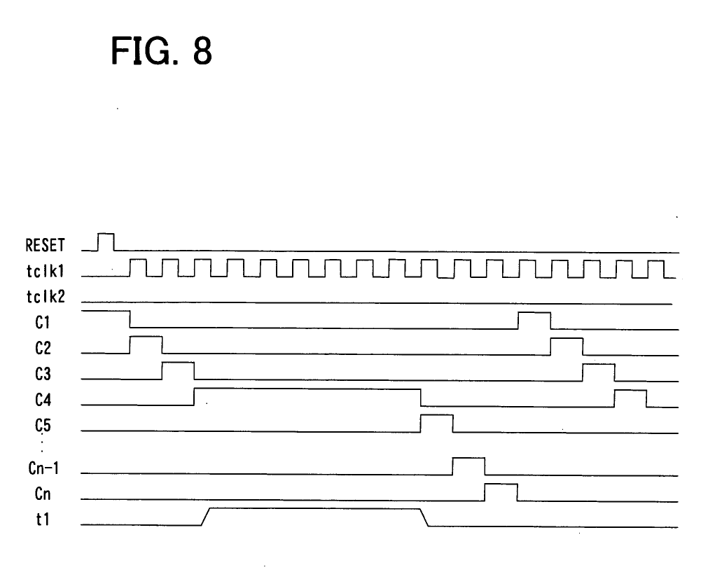

FIG. 8 is a diagram showing operation waveforms of the second counter circuit 26. Referring to FIG. 8, the control logic circuit 9″ first stops the second clock input signal tclk2 and supplies the first clock input signal tclk1 to the second counter circuit 26. According to counting for the signal tclk1, the decimal counter 203 outputs a result of counting. While the clock switching signal t1 is LOW, the selector circuit 201 selects the first clock input tclk1 for supply to the decimal counter 203. The count outputs C1, C2, C3 and C4 of the clock selection signal 21 sequentially go HIGH.

Assume herein that the first-phase clock signal φ1 is selected as the recovered clock 15. Then, assume that the signal s1 of the first selected clock signal 23 goes HIGH, and the signal t1 of the second selected clock signal 24 (constituted from the signals t1 to tn) output from the first counter circuit 22 goes HIGH. Then, the clock switching signal t1 to be supplied to the second counter circuit 26 goes HIGH, and an output of the D-type flip-flop 202 also goes HIGH, in synchronization with the first clock input tclk1. For this reason, the selector circuit 201 switches the signal to the second clock input tclk2 for output. At this point, the second clock input tclk2 is fixed at LOW. For this reason, clock input to the decimal counter 203 is stopped at the second counter circuit 26.

While the clock switching signal t1 is HIGH, the second clock input tclk2 is fixed at LOW. The count output C4 of the clock selection signal 21 (constituted from the count outputs C1 to Cn) is kept at HIGH. In this case, the clock selection circuit 20 selects the fourth-phase clock φ4. In the CDR circuit 7, the first-phase clock φ1 is selected as the recovered clock 15.

Next, it is assumed that the signal t1 of the second selected clock signal 24 changes from HIGH to LOW (which means that the clock switching signal t1 goes LOW). Upon receipt of this clock switching signal t1, the output of the D-type flip-flop 202 goes LOW again. The selector 201 selects the first clock tclk1. The decimal counter 203 receives the clock (first clock tclk1) from the selector circuit 201 and performs counting. That is, the clock selection signal 21 sequentially increases in response to a rise of the clock (tclk1) from the selector circuit 201. That is, as shown in FIG. 8, after the clock switching signal t1 goes LOW, the clock selection signal 21 (constituted from the signals C1 to Cn) is set to HIGH sequentially from the phase C5 subsequent to the phase C4. If the counter circuit has a configuration in which a control operation as described above is performed based on the clock switching signal 204 (t1), the configuration of the counter circuit is not limited to the configuration that selects one of the first and second clock inputs (tclk1 and tclk2), and may be of course other arbitrary configuration.

In the second embodiment of the present invention, shown in FIG. 3, the recovered clock 15 selected by the CDR circuit 7 according to the clock selection signal 21 depends on the transmit circuit delay time (tTx) and the receiver circuit delay time (tRx). Thus, the recovered clock 15 is not uniquely determined. For this reason, when the test is conducted, a state of the second selected clock signal 24 with respect to the clock selection signal 21 needs to be determined in advance. That is, when the clock signal with a certain phase among the multiple-phase clocks 16 is selected at the clock selection circuit 20 as the transmit clock 11, based on the clock selection signal 21, it is necessary to determine in advance which of the second selected clock signal 24 (constituted from the signals t1 to tn) goes HIGH, using measurement or the like.

On the other hand, in the third embodiment of the present invention, as described above, when the fourth-phase clock φ4 of the multiple-phase clocks 16 is selected as the transmit clock 11, selection of the first-phase clock φ1 by the CDR circuit as the recovered clock 15 is managed by the second counter circuit 26, for example.

In the third embodiment of the present invention, by performing clock input just corresponding to the phase of the clock signal selected by the clock selection circuit 20 before a result of the selection of the recovered clock 15 by the CDR circuit 7 is determined, the test can be always started from the same state.

According to each of the embodiments described above, clock connections and all circuits within the CDR circuit can be tested at a high speed in an approach of the loopback test. Further, a failure in the clock selection circuit can also be detected.

Further, according to the third embodiment of the present invention, the test for detection of a failure in the clock selection circuit can be always started in the same state.

In the embodiments described above, one channel configuration (having one input/output terminal 4) is shown. The present invention is not limited to the configuration described above. The present invention can also be, of course, applied to a multi-channel configuration including a plurality of the input/output terminals 4 and pairs of transmit and receiver circuits corresponding to the input/output terminals.

In the embodiments described above, an example (of an I/O Common arrangement) where an output of the transmit circuit 3 and an input to the receiver circuit 6 are connected in common to the input/output terminal 4 is shown. The present invention is not limited to the configuration described above. Naturally, an output terminal with the output of the transmit circuit 3 connected thereto and an input terminal with the input of the receiver circuit 6 connected thereto may be separately provided (which is an I/O Separate arrangement), these terminals may be electrically connected at a time of the test using a tester or the like, or a jig or the like, and then, the loopback test may be performed.

The foregoing description was given in connection with the embodiments described above. The present invention is not limited to the configurations of the embodiments described above, and of course includes various variations and modifications that could be made by those skilled in the art within the scope of the present invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A communication device comprising:
a clock generation circuit that generates multiple-phase clocks including a plurality of clock signals with phases thereof being different to one another; and
a clock and data recovery circuit that receives the multiple-phase clocks from said clock generation circuit, selects from among the multiple-phase clocks a clock signal synchronized with received data to recover data, and outputs the selected clock signal as a recovered clock;
wherein a loopback test for said communication device is conducted by looping back a transmit signal from a transmit circuit thereof to a receiver circuit thereof, supplying the received data from the receiver circuit to said clock and data recovery circuit, and comparing the recovered data from said clock and data recovery circuit with expected value data;
said communication device further comprising a circuit that selects a clock signal of one phase from among the multiple-phase clocks supplied from said clock generation circuit to said clock and data recovery circuit responsive to a clock selection signal, and supplies the selected clock signal as a transmit clock; wherein the loopback test is allowed to be conducted with a delay time of said transmit circuit defined based on the transmit clock being variably set.

2. A communication device comprising:
a clock generation circuit that generates multiple-phase clocks including a plurality of clock signals with phases thereof being different to one another;
a transmit circuit for outputting a signal;
a receiver circuit for receiving a signal;
a clock and data recovery circuit that receives the multiple-phase clocks from said clock generation circuit and selects from among the multiple-phase clocks a clock signal synchronized with input data, thereby recovering data; and
a clock selection circuit that receives the multiple-phase clock signals supplied from said clock generation circuit to said clock and data recovery circuit, selects a clock signal of one phase from among the multiple-phase clocks responsive to a clock selection signal, and outputs the selected clock signal;
at a time of a loopback test, the clock signal selected by said clock selection circuit being supplied to a circuit that generates transmit data for the loopback test and a circuit that latches the generated transmit data, as a transmit clock;
the transmit data being looped back from an output terminal of the transmit circuit to the receiver circuit, and then being supplied to said clock and data recovery circuit from said receiver circuit;
wherein with the change of selection of the clock signal by said clock selection circuit, a delay time from the transmit data is output to when the transmit data is output from said receiver circuit as received data is allowed to be variably set.

3. The communication device according to claim 1, wherein said clock and data recovery circuit outputs a first selected clock signal indicating which clock signal in the order of phases among the CDR multiple-phase clocks has been selected;
the communication device further comprises a first counter circuit that receives the first selected clock signal;
when the first selected clock signal indicates continuous selection of the clock signal of one phase from among the multiple-phase clocks for a predetermined period, said first counter circuit detects the continuous selection, and outputs a result of the detection in the form of a second selected clock signal; and
which clock signal in the order of phases from among the multiple-phase clocks is selected as the recovered clock by said clock and data recovery circuit is thereby enabled to be identified.

4. The communication device according to claim 3, wherein
the multiple-phase clocks include clocks (φ 1 to φ n) with first through nth phases thereof separated at equal intervals;
the first selected clock signal include n signals (s1 to sn) corresponding to the clocks of the first through nth phases, respectively; and
when said clock and data recovery circuit selects as the recovered clock the clock signal of the ith phase from among the clock signals of the first through nth phases of the multiple-phase clocks, in which i is an integer from 1 to n, the ith signal (si) of the first selected clock signal is activated, corresponding to the clock signal of the ith phase.

5. The communication device according to claim 3, wherein said first counter circuit comprises n counters that receives the n signals (s1 to sn) comprising the first selected clock signal from said clock and data recovery circuit, respectively;
each of said n counters performs counting of an input clock signal while a corresponding one of the n signals (s1 to sn) constituting the first selected clock signal is active, and outputs the output signal that is active when a predetermined count value is reached; and
said first counter circuit includes a circuit that performs control so that when one of the n outputs of said n counters is activated, transmission of the clock signal to said n counters is cut off.

6. The communication device according to claim 3, further comprising:
a second counter circuit including:
a selector circuit that receives the first selected clock signal of said first counter circuit as a clock switching signal, and selects one of first and second clock input signals based on the clock switching signal; and
a counter that counts an output of said selector circuit;
a count output of said second counter circuit being supplied to said clock selection circuit as the clock selection signal.

7. The communication device according to claim 6, wherein said counter stops a count operation when the clock switching signal is at a first logic level and clock input from said selector circuit is stopped, and performs the count operation responsive to a clock input from said selection circuit when the clock switching signal is at a second logic level.

8. The communication device according to claim 3, wherein the second selected clock signal comprises n signals (t1 to tn) corresponding to n signals (s1 to sn) of the first selected clock signal, respectively, and one of the n signals of the second selected clock signals is supplied to said second counter circuit as a clock switching signal.
